(19) United States
(12) Patent Application Publication
(10) Pub. No.: US 2006/0148366 A1
(43) Pub. Date: Jul. 6, 2006

(54) Method for manufacturing a polymer oled

(75) Inventors: Franciscus C Dings, Veldhoven (NL); Martin D Bijker, Helmond (NL); Marinus F.J Evers, Heeze (NL)

Correspondence Address: PILLSBURY WINTHROP SHAW PITTMAN, LLP, P.O. BOX 10500, MCLEAN, VA, 22102, US

(73) Assignee: OTB Group B.V., Eindhoven (NL)

(21) Appl. No.: 10/515,067

(22) PCT Filed: May 20, 2003
(86) PCT No.: PCT/NL03/00371

§ 371 Date: Aug. 8, 2005

(30) Foreign Application Priority Data
May 21, 2002 (NL) 1020635

(51) Int. Cl. H01J 9/32

(52) U.S. Cl. 445/25

(57) ABSTRACT

A method for manufacturing a polymer OLED, wherein after the application of a number of active layers onto a substrate to form the OLED, these active layers are encapsulated with at least one sealing, wherein prior to the application of the sealing, the OLED is heated for some time, as a result of which volatile substances present in the active layers evaporate from the OLED, and subsequently the respective sealing is applied. Optionally independently of the heating of the OLED prior to the application of the sealing, the sealing can be formed by at least a UV-setting resist layer which is applied with one of the following techniques; printing, such as inkjet printing, screen printing, tampon printing, offset printing and the like, or a mechanical coating technique, such as spray coating, curtain coating, spin coating and the like.

This invention relates to a method for manufacturing a polymer OLED, wherein after the application of a number of active layers onto a substrate to form the OLED, these active layers are encapsulated with at least one sealing.

In the known polymer OLEDs, such as described, or instance, in WO99/08122, the content of which is to be understood to be incorporated herein by reference, the OLED is sandwiched between two plates which are sealed together. The plates therefore form a housing in which the OLED is accommodated. Also known from practice, is an OLED where the OLED on one side has been formed on a glass substrate plate and on the other side is covered with the aid of a small metal box which is glued onto the glass substrate plate. In the box, a getter material is included. A problem of this practical embodiment is that the manufacture thereof is difficult to automate.

The problem one is faced with is that it should be possible to rapidly manufacture a OLED having a long lifetime. It is to be taken into account here that the active layers, such as, for instance, a PEDOT layer and a PPV layer, of the OLED are highly sensitive to moisture and oxygen. Minor exposure to one of these substances leads to a considerably shorter lifetime. When such exposure does not occur, however, lifetimes of 35,000 hours can be achieved. The glued joint between the metal box and the glass substrate plate or the seal between the two plates from the above-mentioned PCT publication should therefore be particularly gas- and moisture-tight. Even when that condition is met, it is found that also the active polymer layers contain moisture, which evaporates when the OLED is switched on. In the conventional OLEDs, as described, for instance, in the publication mentioned, a getter material may be included in the housing bounded by the two plates. U.S. Pat. No. 6,268,695, the content of which is to be understood to be incorporated herein by reference, discloses an OLED sealing method which utilizes a PECVD process for applying sealing layers. In the use of this method it is not possible to provide getter material under the sealing layer. Accordingly, when the sealing is formed by a vacuum deposition process, the lifetime of the OLED is limited by the release of moisture from the active layers of the OLED during use. It may even happen that the sealing layers after switch-on of the OLED break up under the influence of water vapor released through evaporation, leading to bubble formation under the sealing layers.

The invention contemplates a solution to these problems and to that end provides a method of the type mentioned in the opening paragraph hereof that is characterized in that prior to the application of the sealing, the OLED is heated for some time, as a result of which volatile substances present in the active layers evaporate from the OLED, and subsequently the respective sealing is applied.

As a result of the heating, the volatile substances present in the active layers, such as water vapor, will be released. All volatile substances released during the heating cannot damage the OLED during use anymore, so that the lifetime of an OLED manufactured with the present method is extended.

According to a farther elaboration of the invention, it is particularly favorable when the heating of the not yet encapsulated OLED takes place while the OLED is in a reduced pressure area, so that volatile substances can easily escape from the layers.

Accordingly, heating can take place, for instance, in the process chamber in which subsequently the sealing layer or the sealing housing is provided on the OLED.

The reduced pressure is preferably lower than 1.10⁻¹ mbar.

According to a further elaboration of the invention, heating can be done by an external heating source, such as, for instance, an IR lamp or a resistance heating element.

However, according to an alternative further elaboration of the invention, it is also possible to have the heating take place by switching the OLED on for some time.

This last procedure moreover has the advantage that before the application of the sealing layers, the OLED, and specifically the active layers thereof, enters a stable condition fairly soon after it has been switched on for the first time, in which stable condition the OLED will remain for the greater part of its lifetime. It has been found that OLEDs perish specifically in this initial start period. When the OLED survives this initial start period, however, the chances that the OLED attains its expected lifetime are high. Accordingly, drying out the OLED at the same time constitutes a good test of the correct functioning of the OLED.

According to a further elaboration of the invention, the time during which the OLED is switched on is long enough to obtain a stable light emittance.

As already indicated above, the invention envisages a fast method for the manufacture of OLEDs. To that end, the invention provides a method of the type mentioned in the opening paragraph hereof that is characterized in that the sealing comprises at least a UV-setting resist layer which is applied with one of the following techniques: printing, such as inkjet printing, screen printing, tampon printing, offset printing and the like, or a mechanical coating technique, such as spray coating, curtain coating, spin coating and the like.

Such a manner of applying a UV-setting resist layer has the advantage that application can proceed at high speed whilst forming a considerable layer thickness. Moreover, a very good levelling of the relief structure of the OLED can be accomplished. U.S. Pat. No. 6,268,695, mentioned earlier, shows the application of a polymer layer by a vacuum deposition. With such techniques, only much tier layers can be applied and moreover the extent of levelling of the relief structure of the OLED is much less. The thus applied UV-setting resist layer therefore affords better protection from a mechanical loading of the OLED, a better levelling of the relief structure of the OLED and, by virtue of its considerable thickness, an excellent barrier against moisture and oxygen. Compared with the application of a polymer layer by vacuum deposition, a layer of UV-setting resist that is applied by one of the techniques mentioned can be formed faster by a factor of 20 to 30. The fabrication process is thus considerably shortened in time. Specifically in the case of inset printing, a thick UV-setting resist layer can be rapidly applied selectively at desired positions in a particularly efficient and flexible manner, that is, without the use of special masks. The coating techniques generally do require the use of masks. Over against the slightly lesser flexibility in these coating techniques, however, there are the higher rates of application. This last also applies to printing techniques such as screen printing and offset printing.

According to a further elaboration of the invention, the UV-setting resist layer can be provided with fillers which enlarge the diffusion path length in the layer. Such fillers can comprise, for instance, mica sheets. The mica sheets will align substantially parallel in the resist layer, and moisture or oxygen tending to penetrate through the resist layer will have to find a way around these mica sheets. Thus the moisture or the oxygen must traverse a longer path length through the layer, which considerably reduces the chance of complete penetration through the layer.

According to a further elaboration of the invention, a getter material can be included in the UV-setting resist layer. Such a getter material can ensure that moisture or like volatile gases that are released from the OLED during use are absorbed directly into the getter material and not into the active layers of the OLED. As already indicated hereinbefore, moisture constitutes a great threat to the useful life of the OLED by attacking the active layers thereof. A suitable getter material comprises, for instance, zeolite and/or silicates.

It is naturally preferred when the method for drying out the active layers prior to application of the sealing is combined with the application of a UV-setting resist layer by printing or a mechanical coating technique.

According to a further elaboration of the invention, the sealing can comprise at least a nitride layer, a metal layer, an oxide layer, or a combination of one or more of these layers, and these layers are applied with a PECVD process.

It is here preferred that after the application of at least a top layer of the active layers, which active layers comprise, for instance, a sputtered barium layer and a sputtered aluminum layer, there is applied directly, i.e. without removing the substrate from the reduced pressure area, at least one sealing layer, such as, for instance, an SiNx layer.

This can be accomplished, according to a further elaboration of the invention, in that the process chamber for applying at least a number of the active layers at the same time constitutes the process chamber for applying at least one sealing layer.

According to an alternative further elaboration, the non-removal from the reduced pressure area can be effected by transporting the substrate from the process chamber for applying at least a number of the active layers, via a conveyor arranged in a vacuum space, to a process chamber for applying at least one sealing layer.

Printing, such as inkjet printing, screen printing, tampon printing, offset printing and the like, or mechanical coating techniques, such as spray coating, curtain coating, spin coating and the like are techniques known per se in the subject technical field, not requiring further description here.

The method for applying sealing layers, such as for instance the SiNx layer that is applied with the aid of a PECVD process after the last active layers of the OLED, such as, for instance, barium and aluminum, have been applied with the aid of, for instance, a sputter process, can be carried out, for instance, in an apparatus as described in applicant's earlier patent application WO 02/04697. After the first sealing layers have been applied in the reduced pressure environment, subsequently the thus sealed OLED can be removed from the reduced pressure environment and with one of the techniques mentioned the relatively thick and mechanically strong UV-setting resist layer can be applied.

1. A method for manufacturing a polymer OLED, comprising:
applying a plurality of active layers onto a substrate to form the OLED;
heating the OLED by switching on the OLED for a period of time such that volatile substances present in the active layers evaporate from the OLED; and
encapsulating said plurality of active layers with a sealing.

2. The method according to claim 1, wherein heating the OLED is performed at a reduced pressure, such that said volatile substances easily escape from the active layers.

3. The method according to claim 2, wherein the reduced pressure is less than 10⁻¹ mbar.

4. A method for manufacturing a polymer OLED, comprising:
applying a plurality of active layers onto a substrate to form the OLED;
encapsulating said plurality of active layers by a sealing, the sealing comprising a UV-setting resist layer which is applied with at least one of the following techniques: printing and/or mechanical coating.

5. The method according to claim 4, wherein the UV-setting resist layer comprises fillers which enlarge a diffusion path length in the UV-setting resist layer.

6. The method according to claim 5, wherein the fillers comprise mica sheets.

7. The method according to claim 4, wherein the UV-setting resist layer comprises a getter material.

8. The method according to claim 7, wherein the getter material comprises zeolite and/or silicates.

9. The method according to claim 1, wherein the sealing comprises a UV-setting resist layer, said UV-setting resist layer is applied with at least one of the following techniques: printing and/or mechanical coating.

10. The method according to claim 4, wherein the sealing comprises at least one of a nitride layer, a metal layer, an oxide layer or a combination of one or more of these layers.

11. The method according to claim 4, wherein
encapsulating said active layers with the sealing comprises applying a UV-setting layer on top of an active layer in said plurality of active layers, and
applying the active layer in said plurality of active layers onto the substrate and applying the UV-setting layer on top of the active layer are performed in a reduced pressure area.

12. The method according to claim 11, wherein
applying the active layer in said plurality of active layers onto the substrate and applying the UV-setting layer on top of the active layer are performed in a same process chamber.

13. The method according to claim 11,
further comprising conveying the substrate from a process chamber, wherein applying the active layer onto the substrate is performed, via a conveyor arranged in a vacuum space to a process chamber wherein applying the UV-setting layer on top of the active layer is performed.

14. The method according to claim 4, wherein said printing is selected from the group comprising: inkjet printing, screen printing, tampon printing and offset printing.

15. The method according to claim 4, wherein said mechanical coating is selected from the group comprising: spray coating, curtain coating and spin coating.

16. The method according to claim 4, wherein at least one of said layers is applied by a PECVD process.

17. The method according to claim 11, wherein said active layer is applied using a sputtering method.

18. The method according to claim 1, wherein encapsulating said active layers with the sealing comprises applying a sealing layer on top of an active layer in said plurality of active layers.

19. The method according to claim 18, wherein said sealing layer comprises SiNx.

20. The method according to claim 18 wherein applying said sealing layer is performed at a reduced pressure.

21. The method according to claim 11, wherein an active layer in said plurality of active layers is a barium layer or an aluminum layer.

22. The method according to claim 11, wherein said UV-setting layer comprises SiNx.
